(19) United States
(12) Patent Application Publication
(10) Pub. No.: US 2010/0059117 A1
(43) Pub. Date: Mar. 11, 2010

(54) HYBRID SILICON SOLAR CELLS AND METHOD OF FABRICATING SAME

(75) Inventors: Zhengrong Shi, Wuxi (CN); Tihu Wang, Littleton, CO (US)

Correspondence Address: SNELL & WILMER LLP (OC), 600 ANTON BOULEVARD, SUITE 1400, COSTA MESA, CA, 92626, US

(73) Assignee: WUXI SUNTECH-POWER CO., LTD., Jiangsu, Wuxi (CN)

(21) Appl. No.: 12/526,385

(22) PCT Filed: Feb. 8, 2007
(86) PCT No.: PCT/CN2007/000445

§ 371 Date: Nov. 24, 2009

(51) Int. Cl. H01L 31/18; H01L 31/00

(52) U.S. Cl. 136/258; 438/96; 438/98; 257/E31.032; 257/E31.003

(57) ABSTRACT

A solar cell is provided in which an amorphous semiconductor layer (15) is located on a back surface of a crystalline silicon structure to form a heterojunction. A first contact structure contacts the crystalline layer (14) and a second contact structure contacts the amorphous layer (15). A method of forming the heterojunction solar cell is also provided in which a doped amorphous semiconductor layer (15) is formed on an oppositely doped crystalline silicon layer (14), to form a rear surface heterojunction with the crystalline silicon layer (14). Subsequently a rear surface contact (16) is formed, to contact to the amorphous semiconductor layer (15), and a heavily doped region (13) of the same conductivity type as the crystalline silicon layer (14) is formed in contact with the crystalline silicon layer (14) wherever metal contacts (10) are required contact the crystalline silicon layer (14) to facilitate contact with the subsequently formed metal contact (10).

### FIELD OF THE INVENTION

The present invention relates to the field of silicon solar cells and in particular, it relates to a method of making such solar cells using a hybrid technology with improved energy conversion efficiency and reduced fabrication cost.

### BACKGROUND OF THE INVENTION

Solar cells based on p-type silicon wafers are usually fabricated with a shallow n-type region (emitter) on the light-receiving side by diffusion of an appropriate dopant, such as phosphorous, to convert the top surface layer of the wafer into n-type, followed by passivation of the light-receiving side, for example by hydrogenated silicon nitride, and passivation of the back side, for example by a back-surface field created by a more heavily doped p-type dopant such as Al, and then followed by metallization of both sides for electrical contacts.

However, n-type Czochralski (CZ) silicon wafers have significant advantages over the commonly available boron-doped p-type CZ wafers. This is apparently due to problems associated with the simultaneous presence of both oxygen and boron impurities in standard p-type CZ material that lead to the generation of defects that significantly lower the minority carrier lifetimes in such p-type material. In comparison, silicon wafers without significant oxygen concentration (which is achieved by avoiding the CZ process such as through the use of float-zone wafers) or silicon wafers without significant boron concentration (such as n-type or high resistivity Czochralski wafers) achieve much higher minority carrier lifetimes than the standard p-type CZ wafers that are predominantly used in the commercial production of solar cells. However, most existing equipment and/or processes used in the fabrication of commercial solar cells have been developed for compatibility with p-type wafers and not n-type wafers. Therefore the solar cell industry has yet to incorporate n-type CZ wafers into fabrication processes. Furthermore, for n-type wafers, the use of boron doping is the predominant method of producing p-type regions (emitters). Consequently, merely using n-type wafers will still result in cell structures with regions that simultaneously have both high B and O concentration.

It has been proposed to use a heterojunction produced at the interface between crystalline silicon and an amorphous silicon (a-Si) material layer that is created on the light-receiving surface as a means of avoiding boron doped p-type CZ—Si regions. With this approach n-type CZ wafers are used without the use of any boron doped regions, to retain high minority carrier lifetimes throughout the device.

However, with this approach, the amorphous silicon in the heterojunction structure has very poor conductivity and when used at the light receiving surface, it is not feasible to conduct the generated current in the direction parallel to the cell surface to where the metal contacts are located on the a-Si material. This necessitates the use of a conducting oxide layer (such as indium tin oxide) deposited onto the amorphous silicon layer as shown in prior art. This conducting oxide layer collects the generated charge from the amorphous silicon material and conducts it to where the metal contacts are located thereby minimising the necessity for current flow in the amorphous silicon material. However, a conducting oxide layer adds significantly to the costs of fabricating the solar cells while simultaneously degrading the cell performance through unwanted light absorption and resistive losses such as at the interface with the metal contact. The conducting oxide layer also introduces potential durability problems that may degrade the performance of the cells as they age. This effect is well documented in the literature.

The slight variations in the amorphous silicon layer thickness on the light receiving surface can also have a significant impact on performance. For example, if the amorphous silicon is slightly thicker than optimal, significant absorption of light will occur within the amorphous silicon material which cannot contribute to the cell's generated current. This particularly degrades the cell's response to shorter wavelengths of light. On the other hand, if the amorphous silicon is slightly less than optimal thickness, this will lead to poorer effective surface passivation with a corresponding degradation in device voltage. Even the optimal thickness of the amorphous silicon material is a trade-off between these two loss mechanisms with some loss in short wavelength response and some loss in voltage.

### SUMMARY OF THE INVENTION

According to a first aspect, a solar cell is provided comprising:

i) a crystalline silicon layer having a front, light receiving, surface and a back surface;

ii) an amorphous semiconductor layer forming a heterojunction with the crystalline layer on its back surface; iii) a first contact structure contacting the crystalline layer and a second contact structure contacting the amorphous layer.

The device may be formed on a silicon wafer or on a thin crystalline silicon film on a glass or other suitable substrate.

The second contact structure is in contact with, and located over, the amorphous layer on the rear surface and may be a continuous contact layer or may be an intermittent structure such as a grid or a set of fingers. In the case of a rear-surface n-type self-aligned metallisation interdigitated with the heterojunction structure, the amorphous layer may be continuous over the entire rear surface, or alternatively both the amorphous layer and the second contact grid/fingers may be deposited with the same intermittent structure on the rear so that the metal contact is aligned to the amorphous silicon layer.

The first contact structure may be an intermittent structure such as a grid or a set of fingers located over the front, light receiving surface of the crystalline silicon layer, or in the case of a rear-surface n-type self-aligned metallisation interdigitated with the heterojunction structure, the first contact structure (also on the rear) may be eventually isolated from, but initially located over, the amorphous layer if the amorphous layer is continuous across the entire rear surface. In this case, the first contact will be treated so that it extends through the amorphous layer at spaced locations to contact the back surface of the crystalline silicon layer. In the latter case one of the first and second contact structures will be inter-engaged over the back surface to allow distributed contact to both the crystalline and amorphous regions.

According to a second aspect a method of forming a heterojunction on a rear surface of a precursor to a silicon solar cell, opposite to a front, or light-receiving, surface, comprises:
a) on a doped crystalline silicon layer forming an oppositely doped amorphous semiconductor layer on the rear surface of the silicon layer;
b) a rear surface contact is then formed to contact to the amorphous semiconductor layer;
c) forming heavily doped regions of the same conductivity type with the crystalline silicon layer wherever metal contacts are required on the front surface;
d) forming metal contacts to contact the heavily doped regions;

The method may commence with a silicon wafer or on a thin crystalline silicon film on a glass or other suitable substrate. Preferably, in the case of a wafer, the doped silicon wafer is an n-type silicon wafer, on which surface damage removal, texturing and cleaning are first performed. The front surface of the wafer preferably has a silicon nitride layer applied by a PECVD deposition incorporating phosphorus dopants. This silicon nitride layer is arranged to induce an electron accumulation layer beneath the silicon nitride layer.

The amorphous semiconductor layer is preferably hydrogenated amorphous silicon, hydrogenated amorphous silicon carbide, or hydrogenated amorphous silicon germanium alloy. Hereinafter we shall use hydrogenated amorphous silicon as an example.

The second contact is preferably formed by a layer of metal or layers of metals, such as by sputtering aluminium.

The first contact structure is preferably made with plated metals such as Ni, Cu or Ag on heavily doped n⁺⁺ regions in an n-type crystalline silicon wafer or an n-type crystalline silicon film. The heavily doped n⁺⁺ regions are preferably produced by laser doping of phosphorous dopants.

The n⁺⁺ regions are preferably cleaned before electroless/electro plating of metal contacts, such as nickel followed by copper followed by emersion silver to replace surface atoms of copper with silver. Metal sintering is then preferably performed (if this was not already done after Ni plating.)

Alternatively, in the case of wafer devices, front surface first contacts can be formed before the rear heterojunction formation, in which case an oxide layer is temporarily formed over the rear surface of the crystalline silicon, and removed again prior to forming the amorphous silicon layer of the heterojunction and subsequently the rear metal contacts.

In another alternative method, the front surface structure is formed by;
a. forming a front surface pre-passivation layer by nitridation or oxidation;
b. forming a front surface deposition of n-type hydrogenated amorphous silicon incorporating phosphorus dopants;
c. forming a front surface deposition of silicon nitride incorporating optional phosphorous dopants;

The resulting front structure then has the first contact added as described above.

In a rear-surface n-type self-aligned metallisation interdigitated with heterojunction structure, the first contact to the crystalline silicon wafer or thin crystalline film is formed on the back surface and is laser-doped either through the rear amorphous silicon layer if the amorphous layer is continuous or through the gaps in the rear amorphous silicon layer if the amorphous layer is intermittent. Formation of both the first contact and the second contact on the rear surface comprises the following actions:
a) forming a second contact in an open pattern with positive busbars over the doped hydrogenated amorphous silicon layer;
b) forming front and rear dielectric layers, such as silicon nitride, silicon oxide, or silicon carbide by plasma-enhanced chemical vapour deposition (PECVD), incorporating phosphorus dopants, with a mask to leave exposed the positive metal busbars;
c) laser doping is used on the rear surface to produce n⁺⁺ regions in interdigitated formation with the comb-like metal coated regions;
d) Forming metal contacts on the n⁺⁺ regions.

Preferably the process of forming the contacts in this form of the rear heterojunction device comprises:
a) forming the second contact on the rear surface by sputtering of a metal such as aluminium to form the rear surface contact in a comb-like pattern with positive busbars;
b) using laser doping on the rear surface to produce n⁺⁺ regions in interdigitated formation with the comb-like metal coated regions;
c) performing a chemical clean of n⁺⁺ regions followed by electroless/electro plating of metals, such as nickel followed by copper followed by emersion silver to replace surface atoms of copper with silver to form the first contact to the crystalline silicon layer; and
d) sintering the metals.

In the case of silicon wafers, following the formation of the rear contacts to the silicon wafer, PECVD depositions of hydrogenated silicon nitride, incorporating phosphorus dopants, are performed to the front surface of the silicon wafer. This silicon nitride layer is arranged to induce an electron accumulation layer beneath the silicon nitride layer.

When the rear-surface n-type self-aligned metallisation interdigitated with heterojunction structure is applied to a thin-film n-type crystalline silicon on glass device with a rear surface n-type self aligned metallisation through the use of laser doping as above, the method comprises;
a) forming a crystalline silicon film on a glass substrate;
c) forming an amorphous silicon layer to form a heterojunction with the exposed rear surface of the crystalline silicon layer;
d) forming the second contact on the rear surface by sputtering of a metal, such as aluminium, to form the rear surface contact in a comb-like pattern with positive busbars;
e) laser doping is used on the rear surface to produce n⁺⁺ regions in interdigitated formation with the comb-like metal coated regions;
f) forming metal first contact on the n⁺⁺ regions.

In this case a front surface silicon nitride layer, incorporating phosphorus dopants, is preferably applied to the glass substrate before the crystalline silicon layer is applied. Otherwise the preferred process is similar to that for a doped wafer.

### BRIEF DESCRIPTION OF THE DRAWINGS

Embodiments of the invention will now be described, by of example, with reference to the accompanying drawings in which:

FIG. 1 diagrammatically illustrates a rear heterojunction structure with a front-surface self-aligned metallisation;

FIG. 2 diagrammatically illustrates an intermediate step in one method of formation of a rear heterojunction structure with a front-surface self-aligned metallisation;

FIG. 3 diagrammatically illustrates a rear-surface n-type self-aligned metallisation interdigitated with heterojunction structure;

FIG. 4 diagrammatically illustrates a rear-surface heterojunction structure followed by front-surface self-aligned metallisation through the use of laser doping with a low-temperature dielectric layer;

FIG. 5 diagrammatically illustrates a thin-film n-type crystalline silicon on glass device with a rear-surface n-type self-aligned metallisation interdigitated with heterojunction structure.

### DETAILED DESCRIPTION OF EMBODIMENTS OF A REAR HETEROJUNCTION SOLAR CELL STRUCTURE

Referring to the accompanying drawings, a number of embodiments of solar cells employing rear heterojunction structures are illustrated.

In these embodiments the heterojunction is located at the rear surface removing the requirement for the conducting oxide layer normally required for lateral conductivity in the case when the heterojunction is located on the light receiving (front) surface and also reducing the sensitivity of performance to the thickness of the amorphous silicon layer within the heterojunction structure. In the embodiments described here, the light passes through the crystalline silicon region first, substantially avoiding the situation of having short wavelength light passing through the amorphous silicon layer. This also facilitates the use of metal across the entire rear surface of the amorphous silicon layer therefore avoiding the need for the conducting oxide layer to carry current in the direction parallel to the cell surface.

However the use of the heterojunction at the rear increases the distance that carriers generated near the light-receiving surface have to travel to the collecting junction at the rear. Therefore high resistivity and high quality wafers are preferably used (regardless of whether the structure is developed for use with n or p-type wafers) or the crystalline region is fabricated as a thin film or both. If using n-type wafers, a contacting scheme for the n-type material is required for the top surface (or else interdigitated with the contact to the heterojunction at the rear surface), whereby heavy doping beneath the metal contact is desirable so as to minimise contact resistance and minimise the contribution of the metal/silicon interface to the device dark saturation current. To avoid degradation of the wafer surface or wafer material, no high-temperature thermal processes should be used prior to depositing the amorphous silicon material needed for the heterojunction. Following the deposition of the hydrogenated amorphous silicon, subsequent device processing should also be compatible with the existing structure to avoid degradation of the heterojunction or surface passivation quality.

Conducting the majority carriers from within the bulk to the n-type metal (first) contact (such as the front-surface metal contact) is a challenge in high resistivity wafers without the use of a separate front-surface diffusion of the same polarity, which in this case is not compatible with the use of the heterojunction on the rear. A conventional front-surface diffusion cannot be used after the formation of the rear heterojunction due to the loss of hydrogen from the amorphous silicon or even damage to the amorphous silicon material such as through crystallisation at the temperatures needed. On the other hand, such a diffusion process is also undesirable prior to heterojunction formation due to problems created at the rear surface during the thermal process and associated handling such as through defect generation, surface roughening, contamination of the surface, surface oxidation, or simply unwanted dopants or other impurities diffusing into the surface. Metal contacting schemes used with any of the current commercial cell technologies (such as screen-printed solar cells, buried contact solar cells, point contact solar cells, etc.) are generally unable to achieve all of the above, primarily due to their dependence on high-temperature thermal processes, either in conjunction with necessary diffusion processes or else firing of the metal contacts.

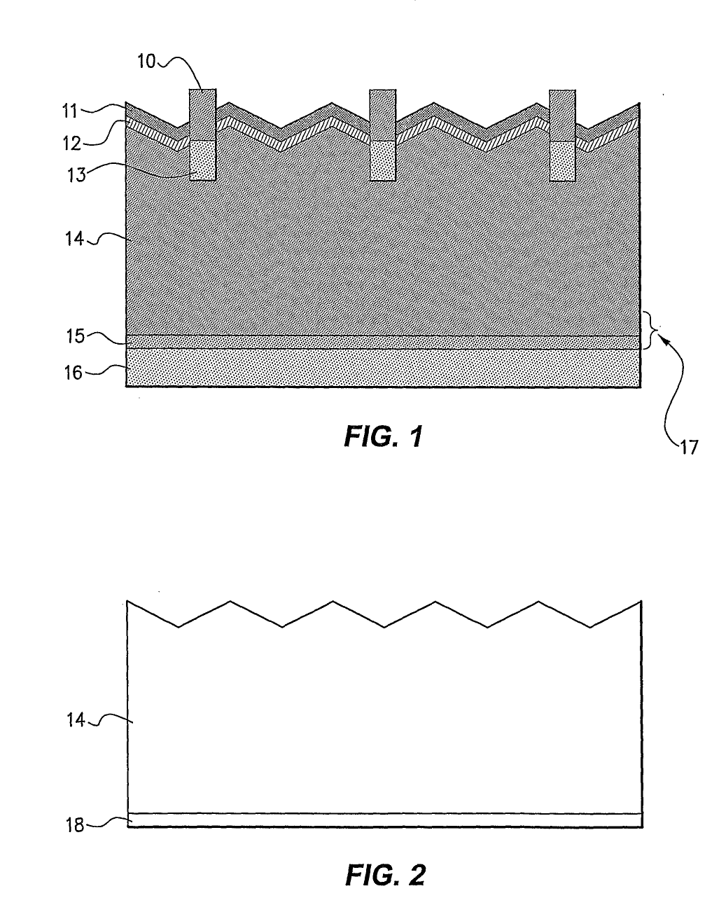

Referring to FIG. 1, the amorphous silicon/crystalline silicon heterojunction structure 17 described above is used at the rear of the cell while a self-aligned electrolessly plated (or electroplated) front surface metallisation 10 is formed over a heavily doped region 13 created by the use of laser doping as described by Wenham and Green in U.S. Pat. No. 6,429,037. This however may not be sufficient as it must be used in conjunction with a technique for conducting the majority carriers from their point of generation to where the metal is located. Conventional diffusion processes, such as are currently used in virtually all commercially manufactured solar cells, are not compatible with the present rear heterojunction design, and three alternative approaches (not currently used in commercially manufactured cells) that are compatible have been identified which will adequately provide the necessary majority carrier conduction.

In a first alternative, formation of laser doped transparent conductors as described by Wenham et alia in Australian Provisional applications Nos. AU 2005926552 & 2005926662 “Low area screen printed metal contact structure and method” (incorporated herein by reference) can be used to conduct the current to the self-aligned metal contacts, whereby the transparent conductors preferably run perpendicularly to the metal lines. In this configuration, all the laser doping for the transparent conductors and the self-aligned metallisation can be done in a single process by using different laser conditions for the transparent conductors whereby the overlying dielectric layer and/or antireflection coating and/or diffusion source are not significantly damaged and thereby still mask the silicon surface from the subsequent plating process. Alternatively, the transparent conductors can be formed prior to a subsequent dielectric/anti-reflection coating/surface passivation layer deposition so as their surfaces are subsequently protected from the plating process that follows the laser doping used for the self aligned metallisation formation.

In a second alternative, electrostatic effects can be used at the surface such as through deliberately incorporating significant levels of charge (positive charge if using an n-type wafer, negative charge if using a p-type wafer) into the surface dielectric layer so as to produce an accumulation layer at the surface to enhance the conduction of majority carriers to the location of either the metal contact or the transparent conductors. For example, incorporating high levels of atomic hydrogen into a silicon-rich silicon nitride layer can achieve this outcome. Other elements can also be potentially used to add positive charge into such dielectric layers. If done properly, these electrostatic effects in conjunction with the dielectric layer can be used to provide superior effective surface passivation. Alternatively, a semiconductor material with an appropriately high bandgap and appropriate doping can be used to give similar band bending near the surface to create such an accumulation layer for improved lateral conductivity for an n-type wafer. The equivalent can be done for a p-type wafer whereby holes are accumulated to the surface to improve the lateral conductivity of the majority carriers which in this case are the holes. An example of such a wide bandgap semiconductor that is compatible with rear-surface heterojunctions is doped hydrogenated amorphous silicon. In this material, the released atomic hydrogen can bond with silicon dangling bonds at the interface to remove the mid-gap states to provide enhanced surface passivation effect. Furthermore, by diffusion of certain elements such as nitrogen or oxygen, the sub-surface region of a crystalline silicon substrate may be converted into a dielectric layer, thereby moving the silicon dangling bonds away from the original crystalline silicon surface and minimizing any negative impact from surface contaminants from imperfect cleaning processes.

In a third alternative, large-area diffusion across the entire top surface can be effected through the use of either rapid thermal processing (RTP) or laser doping in a way that the thermal effects will not degrade the heterojunction at the rear surface. Such techniques can be used with rear heterojunction structures in conjunction with the self-aligned metallisation scheme whereby the top surface RTP or laser diffusion is carried out prior to the laser doping for heavily doped regions to be contacted by the plated metal. In this approach, the same dopant source could be used for both the top surface diffusion and the laser doping for the self-aligned metallisation and/or transparent conductors. For example, the phosphorus source can be incorporated into the silicon nitride antireflection coating and then used as the phosphorus source for top-surface diffusion, transparent conductors and self-aligned metallisation.

In the case of using medium resistivity n-type wafers in the range 1-5 ohms-cm, the sheet resistivity of the wafer itself is adequate to avoid the need for the above approaches for enhancing the lateral conductivity of majority carriers in the wafer to facilitate collection by the first metal contact. Such wafers have demonstrated minority carrier lifetimes high enough for compatibility with a rear junction device design provided wafers are not much thicker than about 200 microns.

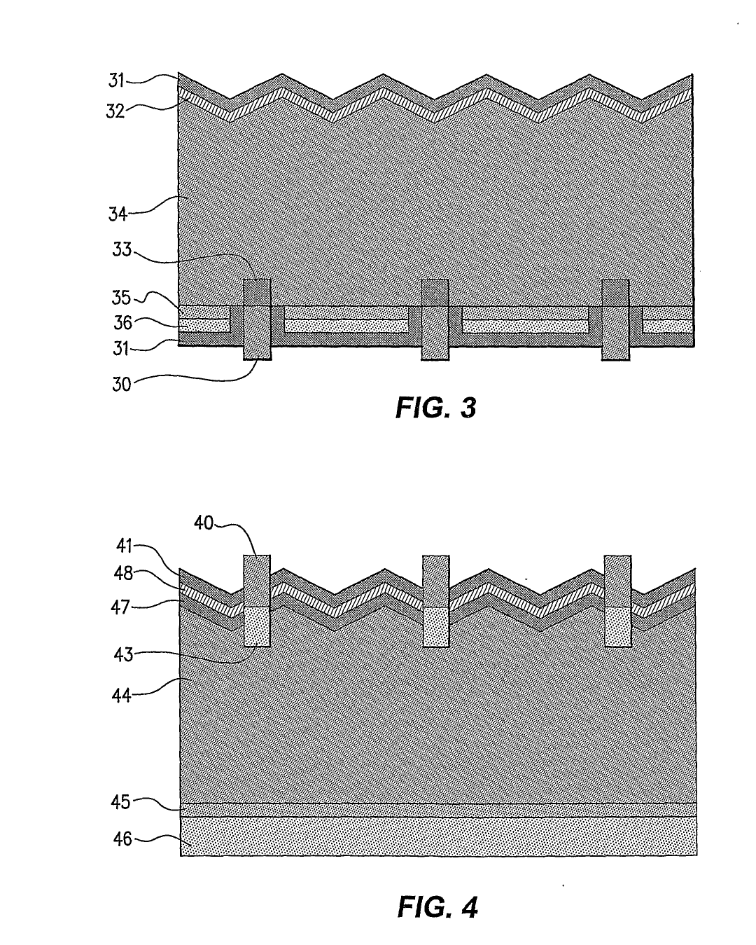

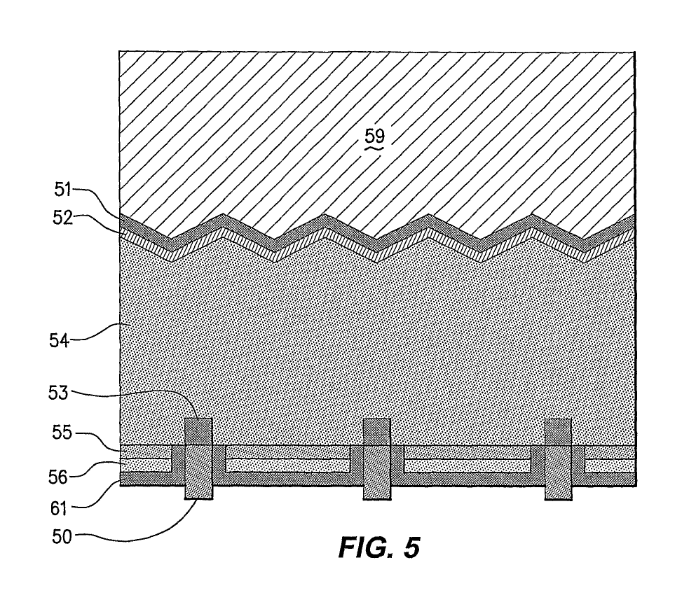

Examples of the Implementation of a rear-surface heterojunction structure.
1. Formation of a rear heterojunction followed by front-surface self-aligned metallisation through the use of laser doping (refer to FIG. 1) comprises the following actions:
   a) on an n-type silicon wafer 14, surface damage removal, texturing and cleaning are performed;
   b) a p-type hydrogenated amorphous silicon layer 15 is then formed by deposition onto wafer rear surface;
   c) a front surface PECVD deposition of silicon nitride 11 is performed incorporating phosphorus dopants. This induces an accumulation layer of electrons 12 beneath the silicon nitride layer 11;
   d) sputtering of metal, 16, such as aluminium, is then used to form a rear-surface (second) contact;
   e) laser doping is used to produce n⁺⁺ regions 13 wherever metal contacts are required on the front surface;
   f) a chemical clean of n⁺⁺ regions 13 is followed by electroless/electro plating of metal 10, such as nickel followed by copper followed by emersion silver to replace surface atoms of copper with silver;
   g) Metal sintering is performed (if this was not already done after Ni plating)
2. Formation of a front-surface self-aligned metallisation through the use of laser doping followed by the formation of a rear-surface heterojunction formation (refer to FIG. 2) comprises the following actions:
   a) on an n-type silicon wafer 14, surface damage removal, texturing and cleaning are performed;
   b) application or growth of a temporary protective rear-surface coating such as PECVD silicon oxide 18;
   c) as in Example 1 above, a front-surface PECVD deposition of silicon nitride 11 is performed, incorporating phosphorus dopants, which induces an electron accumulation layer 12 beneath the silicon nitride layer 11;
   d) laser doping is used to produce n⁺⁺ regions 13 wherever metal contacts are required on the front surface;
   e) the rear-surface protective layer 18 (see FIG. 2) is then removed and the rear surface cleaned;
   f) a p-type hydrogenated amorphous silicon layer 15 is then formed by deposition onto wafer rear surface;
   g) sputtering of metal 16 such as aluminium is then used to form a rear surface contact;
   h) a chemical clean of n⁺⁺ regions 13 is followed by electroless/electro plating of metal 10, such as nickel followed by copper followed by emersion silver to replace surface atoms of copper with silver;
   i) metal sintering is performed (if this was not already done after Ni plating)
3. Formation of a rear-surface n-type self-aligned metallisation through the use of laser doping, interdigitated with a rear-surface heterojunction structure (refer to FIG. 3) comprises the following actions:
   a) on an n-type silicon wafer 34, surface damage removal, texturing and cleaning are performed;
   b) a p-type hydrogenated amorphous silicon layer (either continuous or in a comb-like intermittent pattern) 35 is then formed by deposition onto wafer rear surface;
   c) sputtering of metal 36 such as aluminium is then used to form a rear-surface contact in a comb-like pattern with positive busbars over the amorphous silicon layer 35;
   d) front- and rear-surface PECVD depositions of silicon nitride 31, incorporating phosphorus dopants, are performed with a mask on the rear surface to leave the positive metal busbars exposed;
   e) laser doping is used on the rear surface to produce n⁺⁺ regions 33 in interdigitated formation with the comb-like metal coated regions 36;
   f) a chemical clean of regions 33 is followed by electroless/electro plating of metal 30, such as nickel followed by copper followed by emersion silver to replace surface atoms of copper with silver;
   g) metal sintering is performed (if this was not already done after Ni plating)
4. Formation of a rear-surface heterojunction structure followed by front-surface self-aligned metallisation through the use of laser doping with a low-temperature dielectric layer (refer to FIG. 4) comprises the following actions:
   a) on an n-type silicon wafer 44 surface damage removal, texturing and cleaning are performed;
   b) a p-type hydrogenated amorphous silicon layer 45 is then formed by deposition onto wafer rear surface;
   c) sputtering of metal 46 such as aluminium is then used to form a rear surface contact;
   d) a front-surface pre-passivation layer 47 is formed by nitridation or oxidation;
   e) a front-surface deposition of n-type hydrogenated amorphous silicon 48 is formed incorporating phosphorus dopants;
   f) a front-surface deposition of low-temperature silicon nitride 41 is formed incorporating phosphorous dopants;
   g) laser doping is used to produce n⁺⁺ regions 43 wherever metal contacts are required on the front surface;
   h) a chemical clean of n⁺⁺ regions 43 followed by electroless/electro plating of metal 40 such as nickel followed by copper followed by emersion silver to replace surface atoms of copper with silver;
   i) metal sintering is performed (if this was not already done after Ni plating)
5. Formation of a thin-film n-type crystalline silicon on glass device with a rear-surface n-type self-aligned metallisation through the use of laser doping, interdigitated with rear-surface heterojunction structure (refer to FIG. 5) comprises the following actions:
   a) a silicon nitride layer 51, incorporating phosphorus dopants, is formed on a glass substrate 59 by a PECVD deposition;
   b) a thin-film n-type crystalline silicon layer 54 is formed on the glass substrate over the silicon nitride layer 51;
   c) a p-type hydrogenated amorphous silicon layer 55 is then formed by deposition onto rear surface of the crystalline silicon film;
   d) sputtering of metal 56 such as aluminium is then used to form a rear-surface contact in a comb-like pattern with positive metal busbars;
   e) a rear-surface PECVD deposition of silicon nitride 61, incorporating phosphorus dopants, is performed with a mask to leave the positive metal busbars exposed. Sufficient phosphorus dopants are incorporated so that subsequent laser doping allows the n-type dopants to override the p-type dopants to produce the n++ regions required for the self aligned first metal contact;
   f) laser doping is used on rear the surface to produce n regions 53 in interdigitated formation with the comb-like metal coated regions 56;
   g) a chemical clean of n⁺⁺ regions 53 is followed by electroless/electro plating of metal 50, such as nickel followed by copper followed by emersion silver to replace surface atoms of copper with silver;
   h) metal sintering is performed (if this was not already done after Ni plating)

In summary, what is described above is a crystalline silicon based solar cell having an amorphous silicon heterojunction on the rear for separation of photon-generated electron-hole pairs and laser-doped localized regions within the crystalline silicon material for majority carrier conduction.

Some embodiments incorporate a front (light-receiving side) passivation structure using an impurity diffusion mechanism comprising dopants of the same polarity as the wafer, to create an interface with the more lightly-doped wafer that has moved inward to the silicon bulk before depositions of passivating dielectric films onto the silicon front surface.

Other embodiments incorporate a front (light-receiving side) passivation structure using an impurity diffusion mechanism comprising dopants such as nitrogen or oxygen, to create an interface with the doped wafer that has moved inward to the silicon bulk before depositions of passivating hydrogenated amorphous silicon films followed by passivating low-temperature dielectrics like silicon nitride.

Some embodiments also incorporate a localized front electrode made by laser doping of the silicon front surface in localised regions while simultaneously damaging the overlying passivating dielectric or amorphous silicon layers so as to expose the laser doped silicon surface followed by self-aligned metallization of such regions while the passivating layers mask the remainder of the light receiving surface from forming metal contact.

Embodiments may also use a layer or layers of metal(s) directly deposited on said amorphous silicon film as a back electrode.

In an alternative arrangement, some embodiments may incorporate an interdigitated positive/negative electrode structure on the rear surface made by laser doping over patterned back electrode followed by metallization.

In some embodiments front contacts employ the use of transparent conductors formed by laser doping in conjunction with a front metallisation scheme described above whereby the transparent conductors run perpendicularly or at an angle to the metal contact lines so that the transparent conductors intersect with the heavily doped regions beneath the first metal contact.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A solar cell comprising:
i) a crystalline silicon layer having a front, light receiving, surface and a rear surface;
ii) an amorphous semiconductor layer forming a heterojunction with the crystalline silicon layer on the rear surface;
iii) a first contact structure contacting the crystalline silicon layer and a second contact structure located over the amorphous semiconductor layer and contacting the amorphous semiconductor layer.

2. (canceled)

3. The solar cell as claimed in claim 1 in which the amorphous semiconductor layer is continuous over the entire rear surface.

4. The solar cell as claimed in claim 3 in which the second contact structure comprises a continuous contact layer of contact material.

5. The solar cell as claimed in claim 3 in which the second contact structure comprises a grid of contact material.

6. The solar cell as claimed in claim 1 in which the second contact structure comprises an intermittent structure of contact material aligned with the amorphous semiconductor layer which is arranged in the same pattern.

7. The solar cell as claimed in claim 1 in which the first contact structure is isolated from the amorphous semiconductor layer and the second contact structure and extends through the amorphous semiconductor layer and the second contact structure at spaced locations to contact to the rear surface of the crystalline silicon layer.

8. The solar cell as claimed in claim 7 in which the second contact structure comprises a set of interconnected fingers of contact material.

9. The solar cell as claimed in claim 8 in which the first contact structure comprises a rear-surface n-type self-aligned metallisation which is interdigitated with the heterojunction and the second contact structure.

10. The solar cell as claimed in claim 1 in which the first contact structure located over the front, light-receiving, surface of the crystalline silicon layer comprises an intermittent structure.

11-13. (canceled)

14. The solar cell as claimed in claim 1 in which the crystalline silicon layer comprises a thin crystalline silicon film on a glass substrate.

15. A method of manufacturing a silicon solar cell with a heterojunction formed on a rear surface of a precursor to a silicon solar cell, opposite to a front, or light-receiving, surface, the method comprising:
a) on a doped crystalline silicon layer, forming an oppositely doped amorphous semiconductor layer on a rear surface of the crystalline silicon layer;
b) forming heavily doped regions of the same conductivity type in the crystalline silicon layer wherever metal contacts are required to contact the crystalline silicon layer;
c) forming a first metal contact structure to contact the heavily doped regions;
d) forming a second metal contact structure, being a rear surface contact to contact to the amorphous semiconductor layer.

16. The method as claimed in claim 15 in which the amorphous semiconductor layer is hydrogenated amorphous silicon, hydrogenated amorphous silicon carbide, or hydrogenated amorphous silicon germanium alloy.

17. The method as claimed in claim 15 in which the second contact structure is formed by applying one or more layers of sputtered metals

18. (canceled)

19. The method as claimed in claim 15 in which the first contact structure is formed by plating a metal or metals on heavily doped regions in the crystalline silicon layer.

20. The method as claimed in claim 19 in which the heavily doped regions are produced by laser doping of n-type dopants sourced in a surface layer of the device.

21-24. (canceled)

25. The method as claimed in claim 15 in which the first contact structure is formed on the rear surface and is interdigitated with the heterojunction structure.

26. The method as claimed in claim 25 in which the first contact structure is formed by laser-doping the heavily doped regions through the rear amorphous semiconductor layer and an overlying insulation layer which acts as a dopant source.

27. (canceled)

28. The method as claimed in claim 15 in which the first contact metallisation is self-aligned with the heavily doped regions via openings formed in the insulation layer during formation of the heavily doped regions.

29. The method as claimed in claim 25 in which formation of both the first contact structure and the second contact structure on the rear surface additionally comprises:
e) forming the second contact structure in an comb-like open pattern with positive busbars over the doped amorphous semiconductor layer;
f) forming front and rear dielectric layers, by plasma-enhanced chemical vapour deposition (PECVD), incorporating dopants of the same conductivity type to the crystalline silicon layer, through a mask to leave the positive metal busbars exposed;
g) forming heavily doped regions of the same conductivity type to the crystalline silicon layer by laser doping, in interdigitated formation with the second contact structure;
h) forming metal contacts on the heavily doped regions.

30. The method as claimed in claim 29 in which the dielectric layer is formed as one or more layers of silicon nitride, silicon oxide, or silicon carbide.

31-34. (canceled)

35. The method as claimed in claim 30 in which following the formation of the rear first contact structure via the heavily doped regions to the silicon layer, PECVD depositions of a dielectric layer, incorporating dopants of the same conductivity type to the crystalline silicon layer, is performed to the front surface of the crystalline silicon wafer.

36-40. (canceled)

41. The method as claimed in claim 35 in which the dielectric layer is arranged to induce an electron accumulation layer beneath the dielectric layer.

42. The method as claimed in claim 15 in which a front surface structure is formed by;
m) forming a front surface pre-passivation layer by nitridation or oxidation;
n) forming a front surface deposition of n-type hydrogenated amorphous silicon incorporating the same type of dopants to the crystalline silicon layer;
o) forming a front surface deposition of silicon nitride incorporating optional dopants of the same conductivity type to the crystalline silicon layer.

43. The method as claimed in claim 42 in which the first contact structure is formed on the Front surface before the rear heterojunction is formed, and an oxide layer is temporarily formed over the rear surface of the crystalline silicon, and removed again prior to forming the amorphous semiconductor layer of the heterojunction and subsequently the rear metal contacts of the second contact structure.

44. The method as claimed in claim 15 in which the crystalline layer comprises a thin-film of n-type crystalline silicon on a glass substrate and the method comprises;
p) forming a doped crystalline silicon film on a glass substrate;
q) forming an amorphous semiconductor layer of the opposite conductivity type forming a heterojunction with the exposed rear surface of the crystalline silicon film layer;
r) forming the second contact structure on the rear surface by sputtering of a metal to form the rear surface contact in a comb-like pattern with positive busbars;
s) forming a rear dielectric layer, by plasma-enhanced chemical vapour deposition (PECVD), incorporating dopants of the same conductivity type to the crystalline silicon film, through a mask to leave the positive metal busbars exposed;
t) using laser doping on the rear surface to produce heavily doped regions in interdigitated formation with the comb-like metal coated regions;
u) forming the metal first contact structure on the heavily doped regions.

45-46. (canceled)
